(19) United States
(12) Patent Application Publication
(10) Pub. No.: US 2011/0000153 A1
(43) Pub. Date: Jan. 6, 2011

(54) Photovoltaic Roofing Tile with Fire Suppression

(75) Inventor: Jonathan D. Albert, Philadelphia, PA (US)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: SOLAR ROOFING SYSTEMS, INC., Philadelphia, PA (US)

(21) Appl. No.: 12/919,841

(22) PCT Filed: Mar. 2, 2009
(86) PCT No.: PCT/US09/35696

§ 371 Date: Aug. 27, 2010

Related U.S. Application Data
(60) Provisional application No. 61/032,245, filed on Feb. 28, 2008.

(51) Int. Cl. E04D 13/18; H01L 31/04; E04C 2/20; E04B 1/94

(52) U.S. Cl. 52/173.3; 136/252; 136/256; 52/309.1; 52/232

(57) ABSTRACT

A photovoltaic roofing tile has a substrate, a photovoltaic laminate positioned over the substrate, and a fire suppression material arranged proximate a first end of the substrate. A plurality the photovoltaic roofing tiles are arranged on a roof deck in an overlapping relationship.

### CROSS-REFERENCE TO RELATED APPLICATIONS

The present application claims priority to U.S. Provisional Patent Application No. 61/032,245, which was filed on Feb. 28, 2009, the contents of which are incorporated herein in their entirety.

### BACKGROUND OF THE INVENTION

The present invention relates to photovoltaic (“PV”) roofing tiles. In particular, the present invention relates to a PV roofing tile with a fire suppression capability.

PV roofing tiles, also known as solar power roofing tiles, are well known in the art and are used in both commercial and residential roofs. However, unlike typical roofing tiles, PV roofing tiles are not or cannot be easily made flame retardant by conventional means. For example, conventional roofing tiles typically composed of polymeric or synthetic materials are made flame retardant by the addition of flame retardant additives such as aluminum tri-hydrate, magnesium hydroxide, halogenated fire retardants, and phosphorus flame retardants.

Such additives have various means by which they achieve fire retardation. In the case of aluminum tri-hydrate and magnesium hydroxide, the compounds decompose at elevated temperatures, absorbing energy and releasing water.

While conventional PV roofing tiles are made from glass, PV roofing tile manufacturers are now looking into PV tiles constructed in part with a flexible laminate and a polymeric cover film. The polymeric cover film must be weather resistant and is typically made from a fluoropolymer. While fluoropolymer films can be flame retardant, encapsulants, which are used in the PV roofing tiles, can burn and cannot be easily made flame retardant. As such, encapsulants, such as EVA, can adversely affect the flammability resistance of the PV roofing tile.

As such, there is a need to provide for a roofing tile and, in particular, a PV roofing tile, having fire suppression or flame retardant capabilities to further improve the safety of building materials.

### BRIEF SUMMARY OF THE INVENTION

Briefly stated, the present invention is directed to a photovoltaic roofing tile which includes a substrate having a first substrate surface, a second substrate surface, a first end, and a second end. The first substrate surface faces away from the second substrate surface. The first end is on an opposite side of the substrate from the second end. A photovoltaic laminate is positioned over the substrate. A fire suppression material is arranged proximate the first end of the substrate.

In another aspect, the present invention is directed to a roof assembly which includes a deck having a mounting surface. A plurality of photovoltaic roofing tiles are arranged on the deck in an overlapping relationship. Each photovoltaic roofing tiles includes a substrate having a first substrate surface, a second substrate surface, a first end, and a second end. The first substrate surface faces away from the second substrate surface. The first end is on an opposite side of the substrate from the second end. A photovoltaic laminate is positioned over the substrate. A fire suppression material is arranged proximate the first end of the substrate.

### BRIEF DESCRIPTION OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a partial front perspective view of a PV roofing tile in accordance with a first embodiment of the present invention;

FIG. 2 is a schematic cross-sectional view of the PV roofing tile of FIG. 1 taken along line 2-2 in FIG. 1;

FIG. 3 is a schematic cross-sectional view of a PV roofing tile arrangement in accordance with a second embodiment of the present invention;

FIG. 4 is a schematic cross-sectional view of a PV roofing tile in accordance with a third embodiment of the present invention;

FIG. 5 is a schematic cross-sectional view of a PV roofing tile in accordance with a fourth embodiment of the present invention;

FIG. 6 is a schematic cross-sectional view of a PV roofing tile in accordance with a fifth embodiment of the present invention;

FIG. 7 is a schematic cross-sectional view of a PV roofing tile in accordance with a sixth embodiment of the present invention;

FIG. 8A is a schematic cross-sectional view of a PV roofing tile in accordance with a seventh embodiment in accordance with the present invention;

FIG. 8B is a schematic cross-sectional view of a PV roofing tile in accordance with an eighth embodiment of the present invention;

FIG. 9 is a partial bottom perspective view of the PV roofing tile of FIG. 8A.

FIG. 10 is a schematic cross-sectional view of a portion of a PV roofing tile in accordance with a ninth embodiment of the present invention;

FIG. 11 is a schematic cross-sectional view of a portion of a PV roofing tile in accordance with a tenth embodiment of the present invention;

FIG. 12 is a schematic cross-sectional view of a portion of a PV roofing tile in accordance with an eleventh embodiment of the present invention;

FIG. 13 is a schematic cross-sectional view of a roof assembly having PV roofing tiles in accordance with the first embodiment; and

FIG. 14 is a schematic cross-sectional view of a PV laminate for being attached to the PV roofing tile in accordance with the present invention.

### DETAILED DESCRIPTION OF THE INVENTION

Certain terminology is used in the following description for convenience only and is not limiting. The words “right”, “left”, “lower” and “upper” designate directions in the drawings to which reference is made. The words “inwardly” and “outwardly” refer to directions toward and away from, respectively, the geometric center of the roofing tile and designated parts thereof. Unless specifically set forth herein, the terms “a”, “an” and “the” are not limited to one element but instead should be read as meaning “at least one”. The terminology includes the words noted above, derivatives thereof and words of similar import.

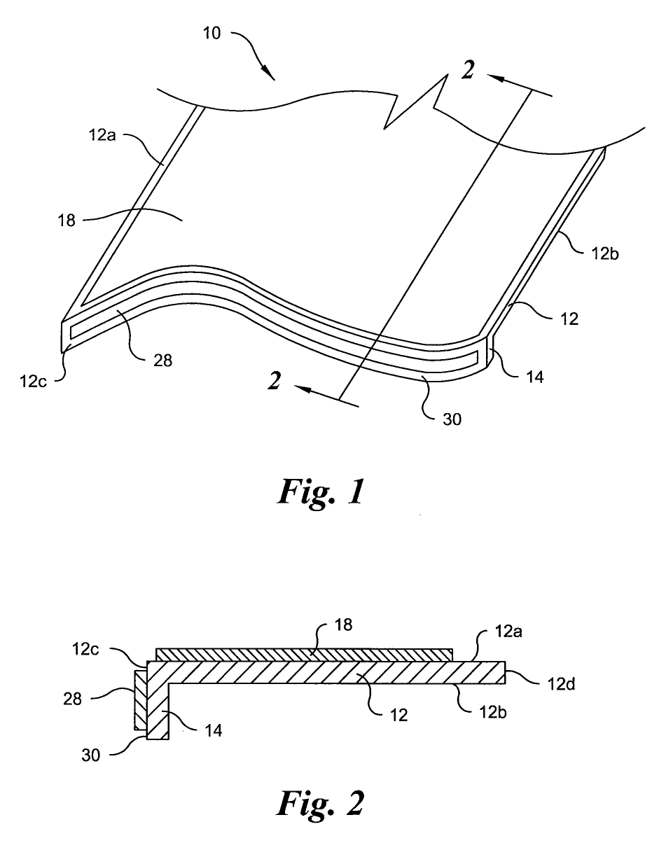

In reference to FIGS. 1 and 2, there is shown a photovoltaic (“PV”) roofing tile 10 in accordance with a first embodiment of the present invention. The tile 10 includes a substrate 12 having a first substrate surface 12a, a second substrate surface 12b, a first end 12c, and a second end 12d. The first substrate surface 12a faces away from the second substrate surface 12b. The first end 12a is on an opposite side of the substrate 12 from the second end 12b. The substrate 12 can be any conventional substrate such as a roofing tile or any other roofing component suitable for use with a PV laminate 18, described in more detail below, that is preferably constructed of building code approved materials. A detailed description of the composition, function, or method of manufacturing the substrate 12 is not necessary for a complete understanding of the present embodiment and is omitted for purposes of convenience only and is not limiting. However, non-limiting exemplary examples of a substrate 12 include synthetic roofing tiles such as slate, cement, and ceramic tiles, metal roofing, asphalt roofing, and tiles comprising Elastocast from BASF, Bayflex from Bayer Material Science, Zytrel and/or Hytrel from Dupont, and the like. The substrate 12 can be composed of a material which is metallic, mineral, organic, polymeric, composite, or a combination thereof, or any other material readily known in the art or to be developed suitable for use as a roofing tile substrate component. The substrate 12 preferably comprises a thermoplastic polymer, such as a thermoplastic polyolefin like polypropylene or polyethylene. The substrate 12 is preferably undulated as shown in FIG. 1, or it can be substantially flat or merely slightly curved without departing from the spirit and scope of the invention.

In the first embodiment the substrate 12 preferably includes a flange 14 extending from a first end 12c at an angle with respect to the first substrate surface 12a. The flange 14 preferably extends generally perpendicular with respect to a plane defined by the substrate 12 or with respect to the first substrate surface 12a, although other angular orientations are possible without departing from the spirit and scope of the invention. The flange 12 preferably extends from the first end 12c a distance to provide a mounting surface for a fire suppression material as described in more detail below.

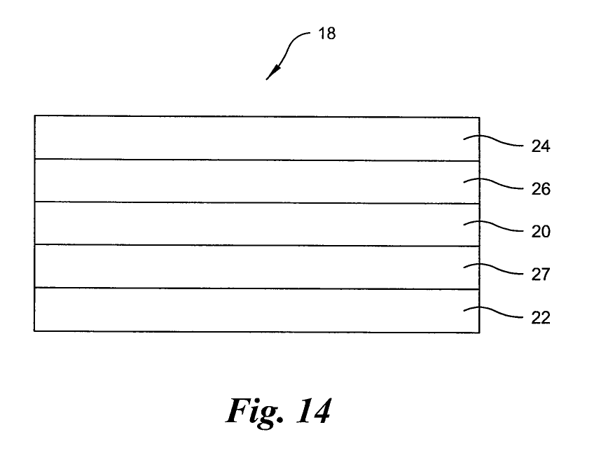

Referring now to FIGS. 1, 2 and 14, the PV roofing tile 10 comprises a photovoltaic (“PV”) laminate 18 positioned over and adhered to, bonded to, mechanically attached to, mounted, or otherwise secured to the first substrate surface 12a of the substrate 12. The PV laminate 18 can be any conventional PV laminate 18 known and used in the art and a detailed description of such laminate is not necessary for a complete understanding of the present embodiment. However, referring to FIG. 1, non-limiting exemplary PV laminates 18 comprise one or more layers of photovoltaic cells 20, a back sheet layer 22, and a transparent layer 24. Preferably, the transparent layer 24 is on one side of the PV cells 20 and the back sheet layer 22 is on another side of the PV cells 20. The reference to PV cells 20 in the present invention shall refer to one or more layers comprising PV cells 20 and/or a metal substrate (not shown) where the PV cells 20 are fabricated on and/or other metal layers and/or semiconductor layers and/or electronics. The transparent layer 24 may be in direct contact with the PV cells 20, or there may be one or more optional layers 26, preferably polymeric layers such as layers comprising EVA, between the transparent layer 24 and the PV cells 20. The transparent layer 24 is preferably positioned to face the sun and is transparent to permit solar radiation to activate the PV cells 20 to generate electricity. The back sheet layer 22 may be in direct contact with the PV cells 20, or there may be other optional layers 27, preferably polymeric layers such as those comprising EVA, between the back sheet layer 22 and the PV cells 20. The PV laminate 18 may also have more than one transparent layer 24 and more than one back sheet layer 22. Also, a substantial portion of the PV laminate 18 is preferably in contact with the substrate 12.

The PV laminate 18 preferably is substantially coextensive with the upper surface of the substrate 12 so as to maximize the electricity-producing area of the PV roofing tile 10. The PV laminate 18 may be arranged so as to not extend all the way to the peripheral portions of the substrate 12. Additionally, placing a PV laminate 18 in portions that will not be exposed to sunlight is inefficient and is preferably avoided. Accordingly, if the PV roofing tiles 10 are going to be arranged in a overlapping relationship (explained more fully below), any portions of the substrate 12 which will eventually be covered by a substrate 12 from another PV roofing tile 10 or non-PV roofing tile are preferably not covered with the PV laminate 18. The area of coverage and of no coverage by the PV laminate 18 is preferably predetermined depending on the intended use of the roofing tiles. It may be possible for the PV laminate 18 to extend to portions of a substrate 12 that will be covered by another substrate 12, except that such portions of the PV laminate 18 will preferably lack the PV cells 20 to reduce cost. Thus, merely extending the polymeric portions of the PV laminate 18 to areas with no sunlight is possible. Preferably, matching the PV laminate 18 to the area with actual sun exposure is preferred because of lower cost and a reduction of the use of potentially flammable materials, such as the polymeric layers of the PV laminate 18.

Referring now to FIGS. 1 and 2, the substrate 12 comprises a fire suppression member 28, which is preferably arranged on the first end 12c of the substrate 12. The fire suppression member 28 is constructed of a fire suppression material, described in more detail hereinafter. The fire suppression member 28 is a separate member that can be integrally formed as part of the substrate 12 or a completely separate component that can be attached, assembled, adhered, or otherwise secured to the substrate 12. The fire suppression member 28 can be attached, assembled, adhered, or otherwise made part of the substrate 12 by any method readily known in the art such as by insert molding, adhesives, fasteners, and the like. The fire suppression member 28 may stand alone or be housed inside a container that is not constructed of a fire suppression material or, alternatively, the container may be constructed of a fire suppression material (not shown).

The fire suppression member 28 may be on any portion of the substrate 12 that is suitable to protect the PV roofing tile 10 and/or underlying structures and/or other PV roofing tiles against fire. The fire suppression member 28 is preferably arranged on or proximate the first end 12c the substrate 12. For example, the fire suppression member 28 may be arranged on the flange 14, preferably the front surface of the flange 14 (this surface corresponds to the front surface 30 of the substrate 12 wherein the substrate comprises a flange 14). The front surface of the flange 14 is the surface which faces away from the substrate 12. The first end 12c of the substrate 12 has a predetermined length depending on the type of tile being used.

For instance, it may have one undulation or several. The fire suppression member 28 preferably extends substantially along the length of the first end 12c, as shown in FIG. 1.

The fire suppression material is preferably an intumescent compound or material but it may comprise a fire agent and/or a flame retardant. The fire suppression material may be molded and comprise a fire suppression additive in combination with a binder where, preferably, the fire suppression additive is 50-90% by weight of the fire suppression material. The fire suppression member 28 may be coated and may comprise a layer comprising a fire suppression additive. The fire suppression additive layer may comprise an intumescent paint or paste, which is a paint or paste which comprises an intumescent additive. The fire suppression additive is preferably substantially comprised of the fire agent, flame retardant, and/or intumescent compound, and may be essentially completely comprised of the fire agent, flame retardant, and/or intumescent compound.

The binder which may be combined with a fire suppression additive can be a polymeric binder. Any polymeric binder readily known in the art and suitable for use as a binding material can be used. Such polymeric binders includes polyethylene, polypropylene, polyethylene waxes, latex binders, polyvinyl alcohol, natural rubber, polyurethane, calcium aluminate cement, combinations thereof, and the like.

The fire suppression member 28 can optionally comprise a colorant or can otherwise be colored to provide for an aesthetic look substantially the same as that of the substrate 12, PV laminate 18, and/or both. For example, the fire suppression member 28 may comprise pigments and/or dies as coloring. Pigments are preferred because of their increased tolerance to UV radiation. Moreover, a paint film, which comprises a paint layer with a protective clear coat, can be arranged over the fire suppression member 28 to provide a desired aesthetic look. The paint layer preferably comprises toner or resin with pigments. The protective clear coat can be a fluoropolymer such as ETFE or a urethane coating. The fire suppression member 28 and/or the paint film, preferably the protective clear coat, may comprise UV blockers such as titanium dioxide and/or stabilizers such as hindered amines to maintain appropriate coloring after long-term exposure to UV radiation.

When the fire suppression member 28 is formed with a fire agent, the fire suppression member 28 acts to suppress or fight a fire to which it is exposed. Such fire agents can include: foams; dry powders of sodium carbonate, sodium bicarbonate, calcium carbonate, calcium sulfate, calcium aluminum phosphate, silica; heat activated foams; heat activated blowing agents such as urea, butyl urea, dicyandiamide, benzene sulfonyl-hydrazide, melamine, guanidine, glycine; chemical foaming agents; azodicarbonamide; and combinations thereof, and the like. A molded fire suppression member 28 comprising a fire agent additive with a high concentration such as 50-90 weight % advantageously allows for a molded fire suppression member 28 to disintegrate and scatter upon being exposed to a sufficient fire hazard or temperature. Moreover, when the fire suppression member 28 is attached to the front surface 30 of the substrate 12, upon disintegration, the disintegrated fire suppression member 28 expands to form a fire wall preventing the fire from moving up or down the roof depending on the wind direction.

When the fire suppression member 28 is formed with a flame retardant, the fire suppression member 28 is made to improve fire resistant properties. Such flame retardants can include aluminum tri-hydrate, magnesium hydroxide, halogenated fire retardants, phosphorus flame retardants, organobromines, organochlorines, phosphorous, organophosphates, red phosphorous, antimony trioxide, boron compounds, borates, ammonium polyphosphate, combinations thereof, and the like. Preferably, when the fire suppression member 28 comprises a flame retardant, the fire suppression member 28 is arranged to cover as much front-facing surface 30 of the substrate 12 as possible. However, this coverage is also possible with fire suppression members 28 comprising a fire agent, flame retardant, and/or intumescent material.

When the fire suppression member 28 is formed with an intumescent compound or material, the fire suppression member 28 acts to form a fire stop by way of a char line formed by the intumescent compound or material. Intumescent compounds or materials per se are well known in the art and non-limiting exemplary intumescent compounds or materials include both hard and soft char producers and those that contain hydrates, sodium silicates, graphite, unexpanded vermiculite, unexpanded perlite, intumescent foam rubber, and/or combinations thereof, and the like.

In reference to FIG. 13, the PV roofing tiles 10 mentioned above can be assembled into a roof assembly. The PV roofing tiles 10 are preferably arranged in an overlapping relationship, preferably on a deck 40 of a roof structure. The term deck 40 is intended to encompass a structure that comprises a roof deck, although not necessarily be limited to only including the roof deck since insulation, weatherproofing, or other layers can be present over or under the roof deck. Moreover, the PV roofing tiles 10 can be placed directly on supporting structures of a roof such as trusses or joists and therefore serve as self-supporting structural replacement to the deck 40. Alternatively, the PV roofing tiles 10 can be placed over an existing roof that already contains tiles or is otherwise functionally complete. Thus, the PV roofing tiles 10 can replace the outermost layer of a roof or can be added on top of the outermost layer of a roof. The PV roofing tiles 10 are preferably arranged on an overlapping relationship where a front end of the substrate 12 of a PV roofing tile 10 is positioned over the back end of the substrate 12 of an adjacent PV roofing tile 10, the front end preferably facing a downward slope of a roof and/or in a direction radially away from the building. Moreover, the PV roofing tiles 10 may be positioned next to one another or overlap in a forward direction or a side direction. The overlapping relationship of roof tiles is well known to those skilled in the art and therefore a detailed description has been omitted for purposes of convenience only and is not limiting.

Additionally, the PV roofing tiles 10 can be in overlapping relationships with other PV roofing tiles 10 and/or with non-PV roofing tiles. For example, in order to improve the fire resistance of a roof assembly, a mixture of PV roofing tiles 10 and non-PV roofing tiles may be utilized. The PV roofing tiles 10 may outnumber the non-PV roofing tiles (or vice-versa) in a defined area of the roof or on the entire roof. Additionally, the PV roofing tiles 10 can be together in clusters with other PV roofing tiles 10 where the clusters are separated by non-PV roofing tiles 10. Alternatively, the PV roofing tiles 10 can be individually separated from other PV roofing tiles 10 by non-PV roofing tiles. Preferably, clustering of PV roofing tiles 10 is preferable in order to facilitate the collection and transmission of electricity generated by the PV roofing tiles 10. Also, the roof assembly may include PV roofing tiles 10 with or without a fire suppression member 28 as well as non-PV roofing tiles with or without fire suppression member 28. Any mixture of these four types of roofing tiles may be included in a roof assembly. Additionally, the orientation of PV roofing tiles 10 on a roof may vary from PV roofing tile 10 to PV roofing tile 10 depending on aesthetics as well as optimum positioning for conversion of electromagnetic radiation into electricity. Additionally, the roof assembly can comprise PV roofing tiles 10 which have the fire suppression member 28 in the same or different locations so as to accommodate different aesthetic and functional requirements, depending on what is visible to consumers and where a fire is more likely to initiate and expand to.

While it is preferred that the fire suppression member 28 be located on the flange 14 at the first end 12c of the substrate 12, it is understood that the present invention is not limited to the exact location or mounting method the fire suppression member. The following is a description of alternative embodiments wherein like numerals indicate like elements throughout. Therefore a complete description of each embodiment is omitted and only the differences between the first embodiment and the alternative embodiment are discussed.

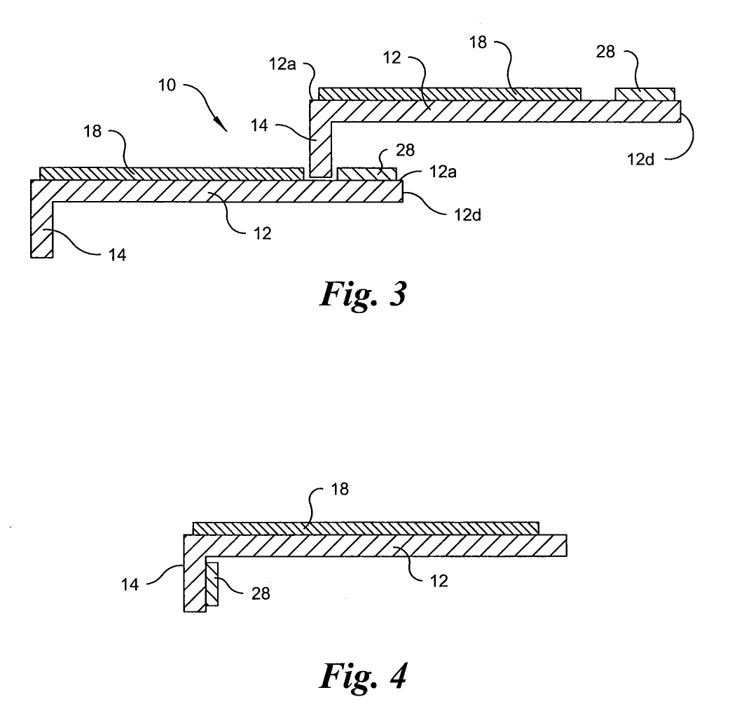

In reference to FIG. 3, there is shown a PV roofing tile 10 in accordance with a second embodiment of the present invention. The main difference between the second embodiment and the first embodiment is that in the second embodiment the fire suppression member 28 is arranged on first substrate surface 12a proximate the second end 12d beneath the next overlapping tile 10. This has the advantage of hiding the fire suppression member 18 from view.

In reference to FIG. 4, there is shown a PV roofing tile 10 in accordance with a third embodiment of the present invention. The main difference between the third embodiment and the first embodiment is that in the third embodiment the fire suppression member 28 is arranged on the backside of the flange 14 so that the fire suppression member 28 is out of view in normal use.

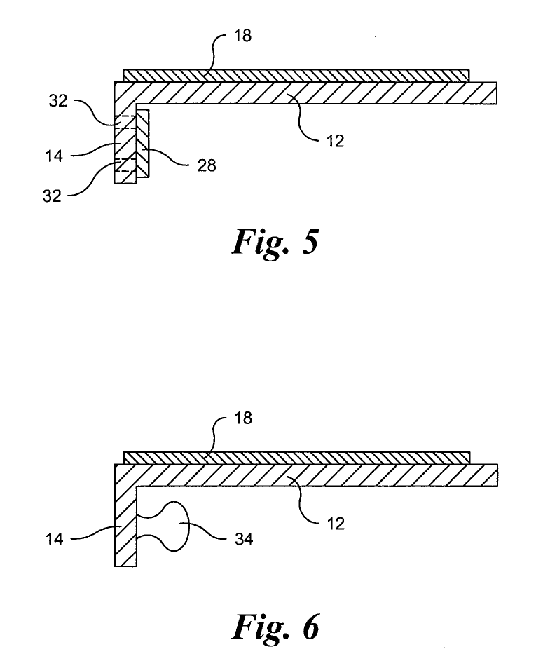

In reference to FIG. 5, there is shown a PV roofing tile 10 in accordance with a fourth embodiment of the present invention. The main difference between the fourth embodiment and the third embodiment is that in the fourth embodiment, the flange 14 includes one or more openings 32 which extend through the flange 14. The openings 32 advantageously allow the contents of the fire suppression member 28 to pass therethrough when configured with fire agent additives that disintegrate upon exposure to a fire or a specific temperature. As a result, the fire suppression member 28, upon disintegration, can travel down the roof to actively fight a fire while remaining hidden from view within the PV roofing tile 10 structure.

In reference to FIG. 6, there is shown a PV roofing tile 10 in accordance with a fifth embodiment of the present invention. The main difference between the fifth embodiment and the first embodiment is that in the fifth embodiment the fire suppression member 28 comprises a fire suppression container 34 having a fire suppressing agent therein. The fire suppression member 28 is mounted, attached, or otherwise secured, preferably, to the backside of the flange 14. The fire suppression container 34 may be attached or mounted by fasteners, adhesives, mounting brackets, combinations thereof, and the like. The fire suppression container 34 can also be secured to the front side of the flange 14 or to the top side of the substrate 12. The fire suppression container 34 can be of any configuration and material that is capable of housing or securing a fire suppressing agent and may be constructed, for example, out of a metal, glass, and/or a composite material.

The fire suppression container 34 may also be configured with a propellant under pressure such as CO₂, nitrogen gas, or any other non-flammable propellant readily known in the art. As such, when the retaining element 36 is released, the contents of the fire suppression container 34, which are under pressure, are forcibly expelled from the fire suppression container 34 through the openings 32 and down the roof to actively fight the fire hazard. The fire suppressing agent can be a fire fighting foam, liquid, gas, or powder. Preferably, the fire suppressing agent is a liquid fire fighting agent, especially in combination with fire suppression container 34 having a pressurized propellant.

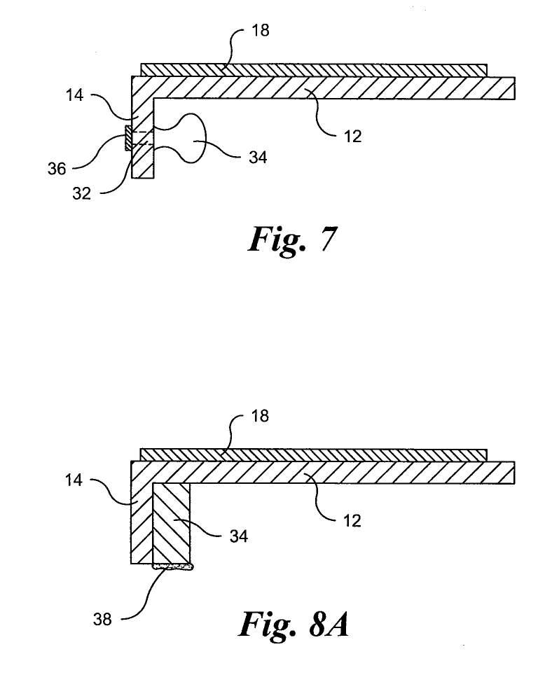

In reference to FIG. 7, there is shown a PV roofing tile 10 in accordance with a sixth embodiment of the present invention. The main difference between the sixth embodiment and the fifth embodiment is that in the sixth embodiment the flange 14 contains an opening 32 which communicates with the fire suppression member 28 to allow the contents of the fire suppression container 34 to pass therethrough to fight a fire. Also, the substrate 18 preferably includes a retaining element 36 such as a cap or stopper, that upon exposure to a fire hazard will melt, disintegrate, or otherwise allow the expulsion of the contents of the fire suppression container 34 to suppress the fire hazard. For example, the retaining element 36 can be a frangible glass vial such as the type used in sprinkler heads. The retaining element 36 can also be made from any low temperature melting metal such as lead alloys, zinc alloys, and/or tin alloys, as well as low temperature melting plastics like wax, polyethylene, polypropylene, polyethylene terephthalate, polymethyl methacrylate, combinations thereof, and the like.

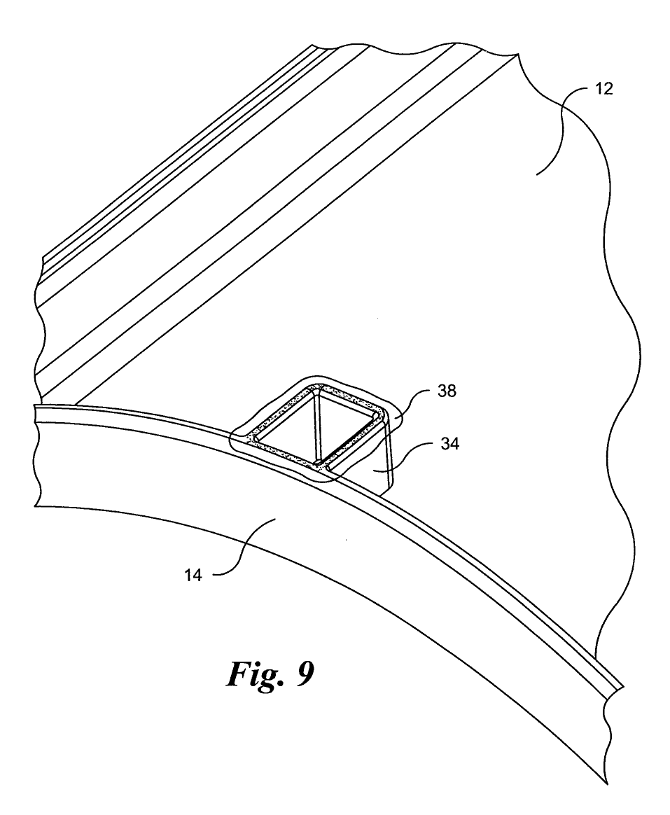

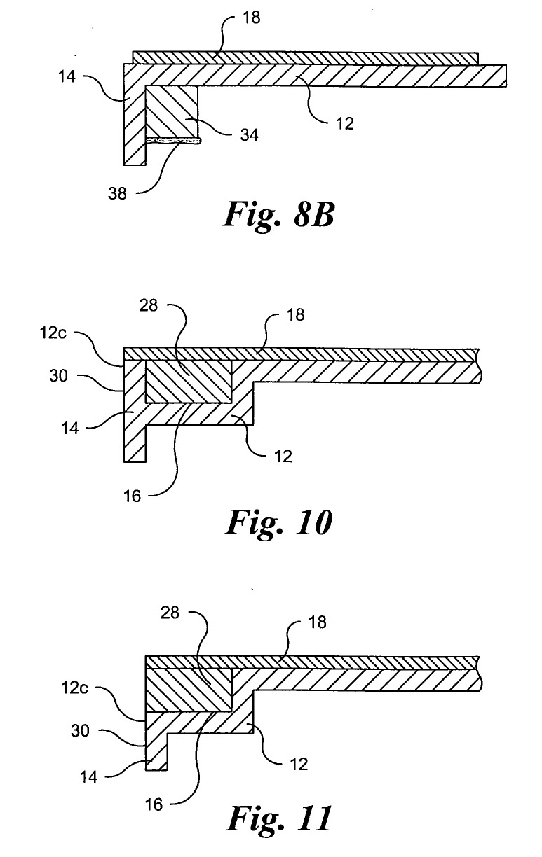

In reference to FIGS. 8A and 9, there is shown a PV roofing tile 10 in accordance with a seventh embodiment of the present invention. The main difference between the seventh embodiment and the first embodiment is that in the seventh embodiment, fire suppression container 34 is arranged on the backside of the flange 14. The fire suppression container 34 is configured as a hollow box-like container, having an open bottom end, that is integrally molded to or otherwise secured to the substrate 12. The fire suppression container 34 is sealed with a sealing layer 38, which can be metallic, polymeric, or a composite, which readily breaks down, disintegrates, detaches from the fire suppression container 34, or otherwise for the expulsion of the contents of the fire suppression container 34. The sealing layer 38 can be sealed to the fire suppression container 34 by any conventional sealing means such as a fastener, adhesive, heat seal, bonding, or the like. For example, the sealing layer 38 can be a foil film that is heat sealed to the fire suppression container 34 and which, upon exposure to a fire hazard, releases the fire suppressing agent within the fire suppression container 34.

In reference to FIG. 8B, there is shown a PV roofing tile 10 in accordance with an eighth embodiment of the present invention. The main difference between the eighth embodiment and the seventh embodiment is that in the eighth embodiment the fire suppression member extends only partially vertically along the backside of the flange 14.

In reference to FIG. 10, there is shown a PV roofing tile 10 in accordance with a ninth embodiment of the present invention. The main difference between the ninth embodiment and the first embodiment is that in the ninth embodiment the substrate comprises a groove 16 in which the fire suppression member 28 is contained. The groove 16 is preferably generally u-shaped in cross-section and positioned at or near an end of the substrate 12, preferably near the first end 12c of the substrate 12, which will face a downward slope in a roof when installed. The groove 16 preferably extends along a substantial width of the substrate 12. More preferably, the groove 16 extends along the width of the substrate 12 except the peripheral edges of the substrate 12. The groove 16 can also extend from one side of the substrate 12 to the other.

In reference to FIG. 11, there is shown a PV roofing tile 10 in accordance with a tenth embodiment of the present invention. The main difference between the tenth embodiment and the ninth embodiment is that in the tenth embodiment, the groove 16 extends to the front surface 30 of the substrate 12 and is therefore generally L-shaped in cross-section.

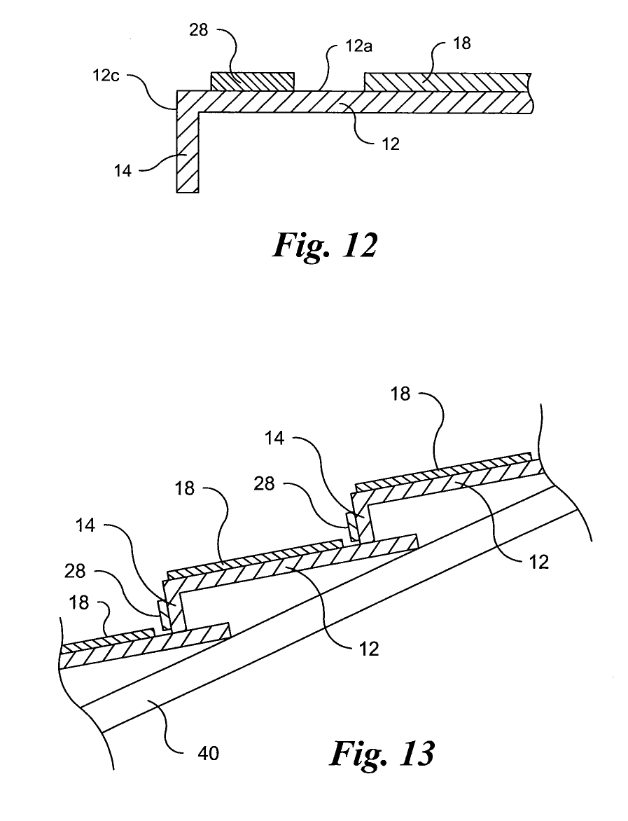

In reference to FIG. 12, there is shown a PV roofing tile 10 in accordance with an eleventh embodiment of the present invention. The main difference between the eleventh embodiment and the first embodiment is that in the eleventh embodiment, the fire suppression member 28 is positioned on the first substrate surface 12a proximate the first end 12c of the substrate 12. The fire suppression member 28 is spaced from the PV laminate 18, although the fire suppression member 28 can be in contact with the PV laminate 18 without departing from the spirit and scope of the invention.

The positions described above regarding the fire suppression member 28 are not limiting and additional positions are contemplated without departing from the spirit and scope of the invention. For example, the fire suppression member 28 can be arranged along any surface or partial surface of the substrate 12 which is not covered with the PV laminate 18. Regardless of where the fire suppression member 28 is arranged on the substrate 12, the fire suppression member 28 can extend partially along the width of the substrate 12, substantially along the width of the substrate 12, nearly completely along the width of the substrate 12 (the entire width except for the peripheral portions), or completely along the width of the substrate 12. The same possibilities are applicable regarding the extension of the fire suppression member 28 along a dimension which is perpendicular to the width of the substrate 12. The width of the substrate 12 is from left to right in FIG. 1. Additionally, the position of the fire suppression member 28 is not limited to being separate from the PV laminate 18. In fact, the PV laminate 18 may include the fire suppression member 28 (or any part thereof) as long as the fire suppression member 28 does not block the active photovoltaic areas of the PV laminate 18 from exposure to the sun. The fire suppression member 28, or any part thereof, can be above, below, or on a side of the PV laminate 18, or it can be in contact with both the PV laminate 18 and the substrate 12, as long as the adhesion of the PV laminate 18 to the substrate 12 and the conversion of solar energy to electricity is not aversely affected. Also, the fire suppression member 28 can be in multiple locations on a single tile.

Additionally, the fire suppression member 28 can also be hidden just beneath the exposed surface of the substrate 12 such that during a fire hazard, the surface would melt away to allow the fire suppression device to activate in an unimpeded manner. Additionally, the fire suppression member 28 can partly extend into a groove 16 of the substrate 12 and partly protrude from the substrate 12, or it can extend from the groove 16 to be flush with a surface of the substrate 12, preferably a front surface 30.

Thus, the present invention permits the safe generation of electricity in rooftops in a versatile manner adaptable to different functional and/or aesthetic requirements.

It will be appreciated by those skilled in the art that changes could be made to the embodiments described above without departing from the broad inventive concept thereof. It is understood, therefore, that this invention is not limited to the particular embodiments disclosed, but is intended to cover modifications within the spirit and scope of the present invention as defined by the appended claims.

1. A photovoltaic roofing tile comprising:
a substrate having a first substrate surface, a second substrate surface, a first end, and a second end, the first substrate surface facing away from the second substrate surface, and the first end being on an opposite side of the substrate as the second end;
a photovoltaic laminate positioned over the first substrate surface; and
a fire suppression material arranged proximate the first end.

2. The photovoltaic roofing tile according to claim 1, wherein the substrate comprises a flange extending from the first end at an angle with respect to the first substrate surface.

3. The photovoltaic roofing tile according to claim 1, wherein the photovoltaic laminate comprises a layer of photovoltaic cells, the layer of photovoltaic cells having a first laminate surface and a second laminate surface, and wherein the photovoltaic laminate comprises a back sheet layer on the second laminate surface and a transparent layer on the first laminate surface.

4. The photovoltaic roofing tile according to claim 1, wherein the photovoltaic laminate is secured to the substrate.

5. The photovoltaic roofing tile according to claim 1, wherein the substrate is constructed of a thermoplastic polymer.

6. The photovoltaic roofing tile according to claim 1, wherein the fire suppression material is arranged on a flange extending from the first end at an angle with respect to the first substrate surface.

7. The photovoltaic roofing tile according to claim 6, wherein the first end has a length and the fire suppression material extends substantially along the length of the first end.

8. The photovoltaic roofing tile according to claim 1, wherein the first end has a length and the fire suppression material extends substantially along the length of the first end.

9. The photovoltaic roofing tile according to claim 1, wherein the fire suppression material is arranged on the first substrate surface proximate the first end and is spaced from the photovoltaic laminate.

10. The photovoltaic roofing tile according to claim 1, wherein the fire suppression material is arranged in a groove formed in the substrate.

11. The photovoltaic roofing tile according to claim 1, wherein the fire suppression material comprises a molded fire suppression additive in combination with a binder.

12. The photovoltaic roofing tile according to claim 1, wherein the fire suppression material comprises a fire agent, a flame retardant, and/or an intumescent material.

13. The photovoltaic roofing tile according to claim 11, wherein the fire suppression material comprises an intumescent material.

14. The photovoltaic roofing tile according to claim 1, wherein the fire suppression material comprises a binder and a fire suppression additive and the fire suppression additive is 50-90% by weight of the fire suppression material.

15. A roof assembly comprising:
a deck having a mounting surface;
a plurality of photovoltaic roofing tiles arranged on the deck in an overlapping relationship, each photovoltaic roofing tile of the plurality of photovoltaic roofing tiles comprising:
a substrate having a first substrate surface, a second substrate surface, a first end, and a second end, the first substrate surface facing away from the second substrate surface, and the first end being on an opposite side of the substrate as the second end;
a photovoltaic laminate positioned over the first substrate surface; and
a fire suppression material arranged proximate the first end.

16. The roof assembly according to claim 15, wherein the overlapping relationship is defined by the second end of the substrate of a first tile being positioned over the first end of the substrate of a second adjacent tile.

17. The roof assembly according to claim 15, wherein each photovoltaic laminate comprises a layer of photovoltaic cells, the layer of photovoltaic cells having a first laminate surface and a second laminate surface, and wherein the photovoltaic laminate comprises a back sheet layer on the second laminate surface and a transparent layer on the first laminate surface.

18. The roof assembly according to claim 15, wherein each photovoltaic laminate is secured to the substrate.

19. The roof assembly according to claim 15, wherein each substrate comprises a thermoplastic polymer.

20. The roof assembly according to claim 15, wherein the fire suppression material is arranged on a flange extending from the first end at an angle with respect to the first substrate surface.

21. The roof assembly according to claim 20, wherein the first end has a length and the fire suppression material extends substantially a long the length of the first end.

22. The roof assembly according to claim 15, wherein the first end has a length and the fire suppression material extends substantially a long the length of the first end.

23. The roof assembly according to claim 15, wherein the fire suppression material is arranged on the first substrate surface proximate the first end and is spaced from the photovoltaic laminate.

24. The roof assembly according to claim 15, wherein the fire suppression material is arranged in a groove formed in the substrate.

25. The roof assembly according to claim 15, wherein the fire suppression material comprises a molded fire suppression additive in combination with a binder.

26. The roof assembly according to claim 15, wherein the fire suppression material comprises a fire agent, a flame retardant, and/or an intumescent material.

27. The roof assembly according to claim 26, wherein the fire suppression material comprises an intumescent material.

28. The roof assembly according to claim 15, wherein the fire suppression material comprises a binder and a fire suppression additive and the fire suppression additive is 50-90% by weight of the fire suppression material.
